(19) United States
(12) Patent Application Publication
(10) Pub. No.: US 2004/0012099 A1
(43) Pub. Date: Jan. 22, 2004

(54) Semiconductor device and manufacturing method for the same, circuit board, and electronic device

(76) Inventor: Toshinori Nakayama, Sakata-shi (JP)

Correspondence Address: EPSON RESEARCH AND DEVELOPMENT INC, INTELLECTUAL PROPERTY DEPT, 150 RIVER OAKS PARKWAY, SUITE 225, SAN JOSE, CA, 95134, US

(21) Appl. No.: 10/375,866

(22) Filed: Feb. 26, 2003

(30) Foreign Application Priority Data
Feb. 26, 2002 (JP) 2002-049513

(51) Int. Cl. B29C 31/00; B28B 11/12; H01L 23/495

(52) U.S. Cl. 257/787; 264/272.17; 264/157

(57) ABSTRACT

A semiconductor device has a substrate 11 on which a wiring pattern 14 is formed, a semiconductor die 20 mounted on the substrate 11, a sealed part 51 sealing the semiconductor die 20 on the substrate 11, and a heat sink 32 for the semiconductor die 20 supported above the substrate 11 by the sealed part 51. The heat sink is in electrical contact with the grounding line of semiconductor die 20.

### BACKGROUND OF THE INVENTION

1. Field of the Invention

The present invention relates to a semiconductor device and a manufacturing method for the same, a circuit board, and an electronic device.

2. Description of the Related Art

Providing for the stability of electrical characteristics in a semiconductor chip is important in the development of a semiconductor device. It is common, for example, to connect a ground potential part of the chip to a conductive foil. This reduces the transmission of noise to other devices in the semiconductor chip, and suppresses noise transmission from other devices. The greater the area of the conductive foil, the better the noise suppression.

Considering the desirability of smaller semiconductor devices, however, it is preferable to use the fewest number of parts as possible in the semiconductor device. It is also important to improve heat radiation from the semiconductor chip in order to improve the reliability of the semiconductor device.

### OBJECT OF THE INVENTION

The present invention is directed to solving this problem and an object of the invention is to improve the heat radiation of the semiconductor device while also stabilizing electrical characteristics.

### SUMMARY OF THE INVENTION

(1) A semiconductor device according to the present invention has a substrate on which a wiring pattern is formed, a semiconductor die mounted on the substrate, a sealed part for sealing the semiconductor die on the substrate, and a heat radiation body for the semiconductor die supported above the substrate by the sealed part. The heat radiation body is electrically connected to part of the wiring pattern.

This heat radiation body is commonly called a “heat sink” and is therefore referred to as a heat sink below.

A heat sink for dissipating heat from the semiconductor die is thus electrically connected to part of the wiring pattern. By electrically connecting the ground potential part of the wiring pattern to the heat sink, for example, the electrical characteristics of the semiconductor chip (i.e. packaged die) can be stabilized. Because the part conducted to the wiring pattern is the heat sink used to dissipate heat from the semiconductor chip, the part count can be reduced and space inside the semiconductor device can be used efficiently.

(2) This semiconductor device further preferably has a wire pulled toward the heat sink with a first end part thereof bonded to the wiring pattern. In this case the heat sink may be electrically connected to the wiring pattern by a middle part of the wire contacting the heat sink.

With this configuration the middle part of the wire contacts the heat sink. By controlling the height of the wire the wiring pattern and heat sink can easily be electrically connected.

(3) Further preferably, the semiconductor die is disposed with the electrode surface thereof facing away from the substrate, and the second end part of the wire is bonded to an electrode of the semiconductor die.

(4) Yet further preferably, the second end part of the wire can be electrically connected to the wiring pattern of the substrate.

(5) Yet further preferably, a pin is disposed to the substrate and extending toward the heat sink, and the heat sink is electrically connected to the wiring pattern due to a distal end part of the pin contacting the heat sink.

With this configuration the pin disposed to the substrate contacts the heat sink. By providing a pin of a specific height, the wiring pattern and heat sink can be more easily connected electrically.

(6) Yet further preferably, the substrate has a through-hole electrically connected to the wiring pattern, and a base end part of the pin is disposed inserted to the through-hole.

With this configuration the pin can be dependably fixed to the substrate.

(7) Yet further preferably, the pin is flexible in the direction of the heat sink.

This configuration alleviates stress applied to the heat sink by the pin.

(8) Yet further preferably, part of the heat sink is curved toward the substrate, and the curved part of the heat sink contacts the wiring pattern.

Because this configuration reduces the part count, the cost can also be suppressed.

(9) Yet further preferably, the heat sink is exposed from the sealed part on the opposite side from the substrate.

This configuration stabilizes the electrical characteristics of the semiconductor die and improves heat radiation.

(10) The heat sink can also be covered by the sealed part on an opposite side from the substrate.

(11) The heat sink can also be exposed at a side part of the sealed part.

(12) Yet further preferably, at least one surface of the heat sink is rough.

(13) Yet further preferably, a plurality of through-holes is formed in the heat sink, and the inside of the through-holes are filled with the material of the sealed part.

This configuration improves adhesion between the heat sink and material of the sealed part.

(14) Yet further preferably, the heat sink has a land part protruding in the direction of the substrate.

This configuration further improves the heat radiation of the semiconductor chip because the distance between the heat sink and semiconductor die is shorter.

(15) A circuit board according to the present invention has a semiconductor device as described above mounted thereon.

(16) An electronic device according to the present invention has a semiconductor device as described above.

(17) A manufacturing method for a semiconductor device according to the present invention includes (a) setting a heat sink in a mold cavity; (b) setting a substrate having a wiring pattern and a semiconductor die mounted thereon in the mold so that the semiconductor die is located inside the cavity; and (c) sealing the multiple semiconductor die and affixing the heat sink by filling the cavity with a sealant. In step (c) the sealant is added with part of the wiring pattern electrically connected to the heat sink.

The invention thus comprised adds the sealant with part of the wiring pattern electrically connected to the heat sink for radiating the heat of the semiconductor die. The electrical characteristics of the semiconductor die can be stabilized, for example, by conducting the ground potential part of the die's wiring pattern to the chip's heat sink. Because the part conducted to the wiring pattern is the heat sink for dissipating the heat of the semiconductor chip, the part count can be reduced and space inside the semiconductor device can be used effectively.

(18) Preferably, a first end part of a wire is bonded to the wiring pattern before step (b), and step (c) adds the sealant with a middle part of the wire contacting the heat sink.

With this configuration the middle part of the wire contacts the heat sink. By controlling the height of the wire the wiring pattern and heat sink can easily be electrically connected.

(19) Yet further preferably, the semiconductor die is disposed with a surface having electrodes facing away from the substrate. In addition, a second end part of the wire is bonded to an electrode of the semiconductor die before step (b).

(20) A second end part of the wire could also be bonded to the wiring pattern of the substrate before step (b).

(21) Further preferably, a pin is disposed to the substrate before step (b), and step (c) adds the sealant with a distal end of the pin contacting the heat sink.

With this configuration the pin disposed to the substrate contacts the heat sink. By providing a pin of a specific height, the wiring pattern and heat sink can be more easily connected electrically.

(22) Yet further preferably, the substrate has a through-hole electrically connected to the wiring pattern, and the base end part of the pin is inserted to the through-hole.

With this configuration the pin can be dependably fixed to the substrate.

(23) Yet further preferably, the pin is flexible in the direction of the heat sink.

This configuration alleviates stress applied to the heat sink by the pin.

(24) Yet further preferably, a part of the heat sink is bent so it is raised before step (a), and step (c) adds the sealant with the bent part of the heat sink contacting the wiring pattern.

Because the part count can be reduced with this configuration, the cost can be suppressed.

(25) Yet further preferably, multiple semiconductor dies are mounted in a planar arrangement on the substrate, an integral set of multiple heat sinks is placed in a mold cavity in step (a); the substrate is set so that the multiple semiconductor dies are located inside the cavity in step (b); and the multiple semiconductor dies are sealed and the set of multiple heat sinks is affixed in step (c).

Because multiple heat sinks can be affixed in one step with this configuration, productivity is improved.

(26) Yet further preferably, this semiconductor device manufacturing method includes (d) producing individual pieces having a heat sink by cutting the sealed part and substrate together with the heat sink set after step (c).

Other objects and attainments together with a fuller understanding of the invention will become apparent and appreciated by referring to the following description and claims taken in conjunction with the accompanying drawings.

### BRIEF DESCRIPTION OF THE DRAWINGS

In the drawings wherein like reference symbols refer to like parts.

FIG. 1 is a semiconductor devices 3 in accord with a first embodiment of the invention.

FIG. 2 shows multiple semiconductor dies on a common substrate for enmasse construction of multiple semiconductor devices of the type shown in FIG. 1.

FIG. 3 is a large heat sink cover to be placed on the structure of FIG. 2 in the construction of multiple semiconductor devices of the type shown in FIG. 1.

FIG. 4 is an intermediate step in the construction of semiconductor devices as shown in FIG. 1, with the large heat sink of FIG. 3 temporarily held in place by a mold.

FIG. 5 is an intermediate construction step showing the removal of the mold of FIG. 4 and the addition of external electrodes.

FIG. 6 shows the cutting of en mass constructed devices into individual semiconductor devices.

FIG. 7 shows a semiconductor device in accord with a second embodiment of the present invention.

FIG. 8 shows a semiconductor device in accord with a third embodiment of the present invention;

FIG. 9 shows a semiconductor device in accord with a fourth embodiment of the present invention;

FIG. 10 shows top view of the semiconductor device of FIG. 9.

FIG. 11 shows a semiconductor device in accord with a fifth embodiment of the present invention;

FIG. 12 shows a variation of the semiconductor device of FIG. 11 in accord with the present invention;

FIG. 13 shows a semiconductor device in accord with a sixth embodiment of the present invention;

FIG. 14 shows an intermediate step in the en mass construction of multiple semiconductor devices in accord with a seventh embodiment of the present invention;

FIG. 15 shows an individual semiconductor device of the type shown in FIG. 14.

FIG. 16 shows an intermediate step in the en mass construction of multiple semiconductor devices in accord with an eighth embodiment of the present invention;

FIG. 17 shows an individual semiconductor device of the type shown in FIG. 16.

FIG. 18 shows an intermediate step in the en mass construction of multiple semiconductor devices in accord with a ninth embodiment of the present invention;

FIG. 19 shows an individual semiconductor device of the type shown in FIG. 18.

FIG. 20 shows a semiconductor device in accord with the present invention mounted on a circuit board.

FIG. 21 shows a notebook type personal computer in which a electronic device in accord with the present invention may be integrated.

FIG. 22 shows a cellular telephone in which a electronic device in accord with the present invention may be integrated.

### DESCRIPTION OF THE PREFERRED EMBODIMENTS

Preferred embodiments of the present invention are described below with reference to the accompanying figures. The invention shall not, however, be limited to the following embodiments.

Embodiment 1

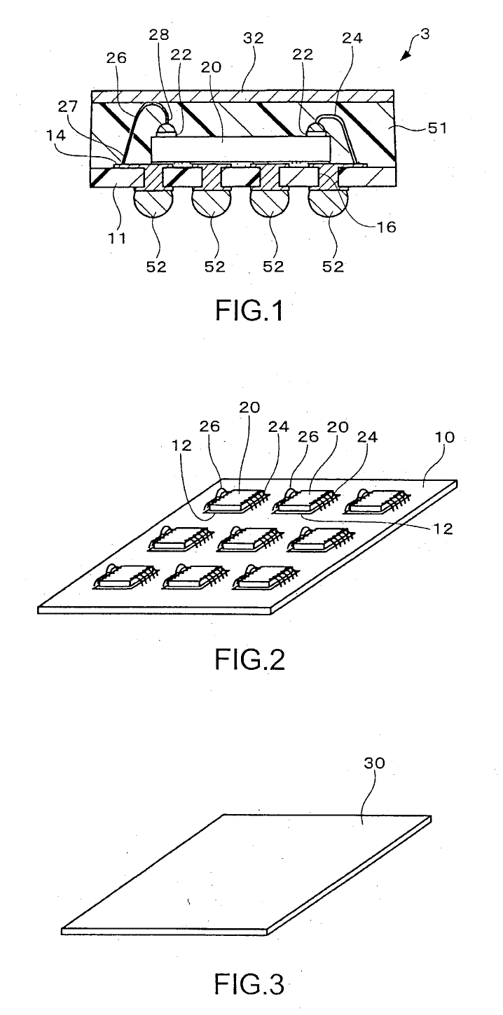

FIG. 1 to FIG. 6 show a manufacturing method for a semiconductor device, or chip, 3 according to a first embodiment of the invention. FIG. 1 shows a semiconductor device 3 according to this embodiment of the invention. This semiconductor device 3 has a substrate 11, semiconductor die 20, sealed part 51 for sealing the semiconductor die 20, and a heat sink 32 for dissipating heat from the semiconductor die 20.

The substrate 11 is called the interposer of the semiconductor device. The substrate 11 could be made from organic (such as a polyimide substrate) or inorganic (a ceramic or glass substrate) materials, or a hybrid (a glass-epoxy substrate) of these. The planar shape of the substrate 11 is not particularly limited but is typically rectangular. The substrate 11 could be a single or multiple layer substrate.

The substrate 11 also has a wiring pattern 14 composed of multiple lines. The wiring pattern 14 is formed on either one or both sides of the substrate 11. Multiple through-holes 16 may also be formed in the substrate 11 for electrically connecting one side to the other. The through-holes 16 can be filled with a conductive material, or the inside walls can be plated. This enables electrical connections to be made from both sides of the substrate 11.

The shape of the semiconductor chips 20 is not specifically limited, but is typically a rectangular parallelepiped (including a cube) as shown in FIG. 1. The semiconductor die 20 is an integrated circuit on a semiconductor substrate and may be composed of multiple electrical components such as transistors and memory elements, not shown in the figures. Each semiconductor die 20 also has at least one (and typically multiple) contact electrodes 22 enabling electrical connection to the integrated circuits on die 20. The contact electrodes 22 can be formed on two or four outside edges of the semiconductor die 20 surface, or can also be formed in the interior, such as the center area, of the die surface. The contact electrodes can be formed of aluminum, copper, or other electrically conductive material. A passivation film, or layer, (not shown in the figure) is formed covering the semiconductor die 20 including the ends of the electrodes 22 but not their middle. The passivation film could be formed from, for example, SiO₂, SiN, or a polyimide resin.

Semiconductor chip 20 is mounted on the substrate, i.e. interposer, 11. In the example shown in FIG. 1, the semiconductor die 20 is mounted with the surfaces having the contact electrodes 22 (i.e. the surface having the die's active area) facing away (up) from substrate 11, i.e. the interposer. In other words, the semiconductor die 20 is mounted face-up on the substrate 11. The semiconductor die 20 can be bonded to the substrate 11 with adhesive.

In the example shown in FIG. 1 one semiconductor die 20 is mounted on the substrate 11. In another version, multiple semiconductor dies could be built in layers on a single substrate 11. The present embodiment can be applied in this case by replacing the semiconductor die on the top layer with this semiconductor die 20 and surrounding construction. The present invention can also be applied to a stacked semiconductor device.

The semiconductor die 20 is electrically connected to the wiring pattern 14. Wire 24 can be used to electrically connect die 20 to wiring pattern 14. In this case a ball bump method can be used. More specifically, the tip of the wire 24 drawn outside the tool (such as a capillary) is melted into a ball, the end is thermocompression bonded to the electrode (preferably also using ultrasonic vibration) to electrically connect the wire 24 to the electrode 22. After the wire 24 is bonded to the electrode 22 of the semiconductor die 20, it is then bonded to the wiring pattern 14 of the substrate 11, for example. In this case a bump is formed on the contact electrode 22 as shown in FIG. 1.

The sealed part 51 on substrate 11 seals the semiconductor chip 20. The sealed part 51 could be, for example, a resin material (such as epoxy resin). The sealing method is not specifically limited, and could involve, for example, filling the cavity of a chip package with a sealing material, or applying a bonding technique.

The heat sink, i.e. heat radiating body, 32 radiates the heat of the semiconductor die 20 way from device 3. The heat sink 32 is preferably made from a material suitable for heat exchange, but the material itself is not specifically limited. It could, for example, be a copper or iron alloy. In the example shown in FIG. 1 the heat sink 32 is formed as a sheet. This simplifies processing and thereby helps reduce the cost. The heat sink 32 can be formed by integrally processing a single member, or by integrally combining multiple members. It can, for example, be chemically processed by half-etching or plating (electrolytic or electroless plating), or mechanically processed by means of pressing or cutting.

A metal film (such as a plated film) not shown in the figures may be formed on the heat sink 32. A metal film could, for example, be formed on the externally exposed part (the exposed part facing away from the sealed part 51 in FIG. 1) of the heat sink 32. Nickel plating could be used as the metal film if the heat sink 32 is made from a copper material, for example. This improves the thermal conductivity of the heat sink 32.

In the example shown in FIG. 1 the exposed part of the heat sink 32 (i.e. the part not in facing sealed part 51) faces away from the substrate 11. This improves the heat radiation of the semiconductor die 20.

As shown in FIG. 1 a plurality of external electrodes 52 can be added onto substrate 11. The external electrodes 52 can be solder balls. The external electrodes 52 can be coupled to contact areas, i.e. lands, in the wiring pattern 14 of the substrate 11. In the example shown in FIG. 1 the external electrodes 52 are located at the through-holes 16.

With reference to FIG. 2, multiple dies 20 are shown on corresponding mounting areas 12 of a single substrate plate 10. Each of the multiple dies 20 has a set of coupling lead wires 24. Of the multiple wires 24 bonded to each semiconductor die 20, part of the wires 26 (only one wire 26 per semiconductor die is shown in FIGS. 1 and 2, but there could be plural wires 26) make contact with heat sink 32 (as shown in FIG. 1) in this embodiment of the invention. FIG. 1 is a sectional view of one semiconductor device 3 cutting through one wire 26. FIG. 3 shows a heat sink cover sheet 30 for covering the multiple dies 20 shown in FIG. 2 and making contact with each die's wire 26.

This wire 26 can be made from the same material (a metal material, for example) and using the same method as the above-described wire 24. Wire 26 can be formed at the same time as wire 24 in the wire bonding process of the semiconductor die 20. Alternatively, the material of wire 26 can be different from the material of wire 24, and is not particularly limited insofar as it is an electrically conductive material.

Returning to FIG. 1, wire 26 has first and second ends 27 and 28. The second end 28 is the end opposite from the first end 27. The first end 27 is bonded to the wiring pattern 14 (at a land, for example). In this case a bump (not shown in the figure) could be disposed therebetween. Then, in the example shown in FIG. 1, the second end 28 is bonded to a contact electrode 22 of the semiconductor die 20. A bump could also be disposed therebetween. Alternatively, if the material of wire 26 and the bump are the same, the second end 28 could also include the bump.

As shown in FIG. 2, the loop of wire 26 is higher than the loops of the other wires 24. More specifically, as shown in FIG. 1, the middle section of this wire 26 (the part, such as the peak of the loop, excluding first and second ends 27 and 28) is drawn towards the heat sink 32 so that it will be higher than the middle parts (such as the peaks) of wires 24.

In other words, wire 26 draws away from the second end 28 on contact electrode 22 toward the heat sink 32 to a height permitting it to contact the heat sink 32. The wire 26 then draws from the middle section contacting the heat sink 32 toward the substrate 11 and electrically connects to the wiring pattern 14 at the first end 27. That is, the heat sink 32 is electrically connected to the wiring pattern 14 as a result of the middle section of wire 26 contacting the heat sink 32.

In a semiconductor device according to this embodiment of the invention the heat sink 32 for radiating the heat away from the semiconductor die 20 is electrically connected to part of the wiring pattern 14. The electrical characteristics of the semiconductor die 20 can be stabilized by, for example, conducting the ground potential part of the wiring pattern 14 to the heat sink 32. That is, the transmission of noise from the semiconductor die 20 to other devices, and the susceptibility to noise of die 20 from other devices, can be reduced.

The part of the heat sink 32 radiating heat from the semiconductor die 20 is an electrically conductive part in electrical contact with wiring pattern 14. The number of parts can therefore be reduced, and space inside the semiconductor device 3 can be used more efficiently. Moreover, the noise-reducing effect can be improved and the heat radiation of the semiconductor chip 20 can be further improved by increasing the area of the heat sink 32.

With the example as shown in FIG. 1 the wiring pattern 14 and heat sink 32 can be electrically easily connected by controlling the height of wire 26 (i.e. the height of the loop on wire 26). Furthermore, because the wire 26 is flexible in the direction of the heat sink 32, positive contact can be made with the heat sink 32 while keeping stress on the heat sink 32 low.

A method of manufacturing a semiconductor device according to this embodiment of the invention is described next below. FIG. 2 to FIG. 6 show an example of a manufacturing method for the semiconductor device shown in FIG. 1. The following example includes a step for sealing multiple semiconductor dies 20 on substrate plate 10 en masse to produce multiple semiconductor device 3. It should be noted that a semiconductor device manufacturing method according to this embodiment of the invention shall not be so limited, and one could seal, i.e. package, each semiconductor die 20 individually.

A substrate plate 10 is first prepared as shown in FIG. 2. After dicing the substrate plate 10, each slice of substrate plate becomes a substrate interposer 11 of a corresponding semiconductor device 3, as shown in FIG. 1. Multiple mounting areas 12 are formed on substrate plate 10 for mounting multiple semiconductor dies 20. The mounting areas 12 are formed on either one or both sides of substrate plate 10. In the example shown in FIG. 2 the multiple mounting areas 12 are formed in a matrix pattern of multiple rows and columns on the surface of the substrate plate 10.

As shown in FIG. 2 a semiconductor die 20 is mounted in each of the multiple mounting areas 12 on substrate plate 10. The multiple semiconductor dies 20 are arranged flat on substrate plate 10. In the example shown in FIG. 2, the semiconductor dies 20 are preferably bonded with its electrodes facing up (face-up bonding).

A wire bonding process comes next. More specifically, wires 24 and 26 are wire bonded to electrically connect semiconductor die 20 to wiring pattern 14. Wires 24 and 26 can be formed at the same time using the same manufacturing equipment. Each die 20 could be wire bonded separately. Alternatively, multiple wires 26 (or multiple wires 24) could be formed at a time to multiple semiconductor dies 20 after forming the multiple wires 24 (or multiple wires 26) at a time to the multiple semiconductor dies 20. The loop of wire(s) 26 is formed taller than the loop in wires 24. With reference to FIG. 3, heat sink sheet 30 is used to cover multiple dies 20 of FIG. 2 and will form multiple heat sinks 32 for dissipating heat from the multiple semiconductor dies 20. In other words, a set of multiple heat sinks 32 is integrally formed from heat sink sheet 30. When the heat sink sheet 30 is cut into individual pieces, each piece becomes the heat sink 32 of an individual semiconductor die 20.

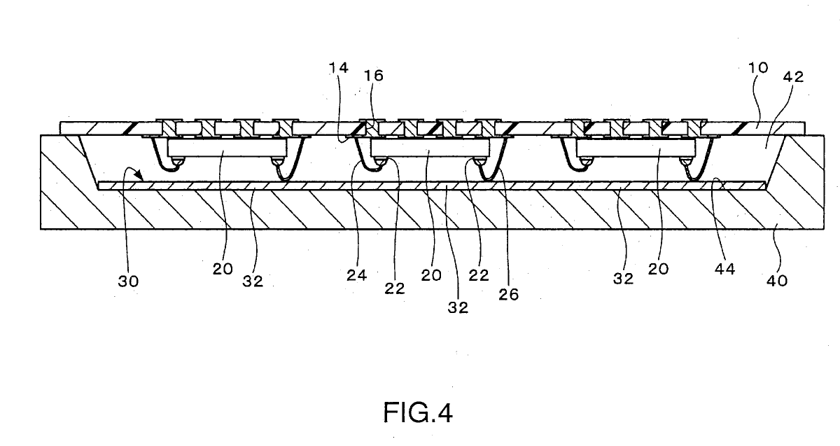

With reference to FIG. 4, in this embodiment of the invention, a mold 40 is used to fix the heat sink sheet 30 over substrate plate 10 and concurrently seal the multiple semiconductor dies 20 on substrate plate 10.

The mold 40 has a cavity 42. The cavity 42 is preferably conformed to a size (width and depth) capable of housing multiple semiconductor dies 20. The bottom 44 of the cavity 42 can be a flat surface.

As shown in FIG. 4, the heat sink sheet 30 is set in against the inner bottom 44 of mold 40. If the planar shape of the heat sink sheet 30 conforms (such as by having the same shape) to the planar shape of inner bottom 44 (or has a shape smaller than bottom 44) such that it can traverse the depth of cavity 42, heat sink sheet 30 can be easily positioned in the cavity 42 of mold 40 by simply dropping heat sink sheet 30 into cavity 42.

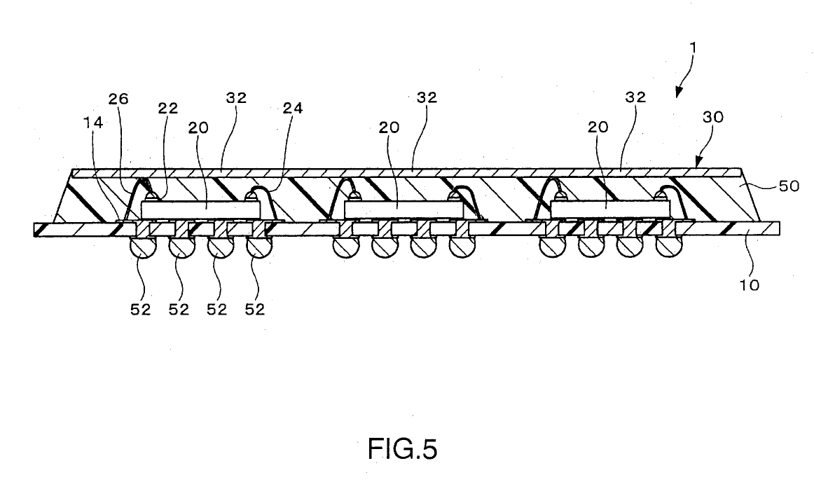

In the example shown in FIG. 4, the heat sink sheet 30 (the part that eventually becomes the heat sink 32 of each chip package) is set in contact with the inner bottom 44 of mold 40. More specifically, heat sink sheet 30 is placed with one side thereof contacting the bottom 44 of cavity 42. This enables the side of heat sink 32 (to be created later) that faces away from substrate 10 to be uncovered by a filling sealant 50, shown in FIG. 5. Heat radiation from semiconductor die 20 can therefore be improved. Furthermore, because the sealant 50 does not penetrate the area where heat sink sheet 30 contacts mold 40, the mold 40 needs less frequent cleaning due to adhesion of sealant 50.

Returning to FIG. 4, after heat sink sheet 30 is placed in cavity opening, 42 of mold 40, substrate plate 10 is placed on the top of mold 40 with dies 20 entering cavity 42. The multiple semiconductor dies 20 are then sealed en masse by flowing sealant 50 (shown in FIG. 5) into cavity 42. More specifically, the sealant fills cavity 42 with the middle loop of wires 26 touching heat sink sheet 30. The sealant is preferably a resin. In this case, it can be called a molding resin. Productivity can be thus improved by concurrently sealing the multiple semiconductor dies 20 to produce multiple semiconductor chips 3 en masse.

As shown in FIG. 5, sealant 50 is thus disposed between the multiple semiconductor dies 20 and the heat sink sheet 30. The heat sink sheet 30 is bonded to substrate plate 10 by the sealant 50. More specifically, the heat sink sheet 30 can be bonded to substrate plate 10 by filling the space therebetween (i.e. cavity 42) with sealant 50.

A semiconductor device 1 incorporating multiple semiconductor dies 20 as shown in FIG. 5 can thus be manufactured. The semiconductor device 1 includes a substrate plate 10, the multiple semiconductor dies 20, sealed part 50 sealing the multiple semiconductor dies 20, heat sink sheet 30 integrally providing a common ground to the multiple dies 20, and wiring patterns for routing the lead wires from dies 20. In the example shown in FIG. 5, the side of the heat sink sheet 30 that faces away from substrate plate 10 is not in contact with sealed part 50. If desired, semiconductor device 1 could be used as a multi-chip package, but since in the present case all dies 20 are preferably the same, semiconductor device 1 can be diced in a later process into individual chip components. In other words, the structure of semiconductor device 1 can be an intermediate process step in the manufacture of multiple individual semiconductor devices 3 (see FIG. 1).

A plurality of external electrodes 52 can be positioned on substrate plate 10, as shown in FIG. 5, before the step for dicing the semiconductor device 1. Productivity is excellent by thus forming the external electrodes 52 for multiple semiconductor devices 3 in one step at this time.

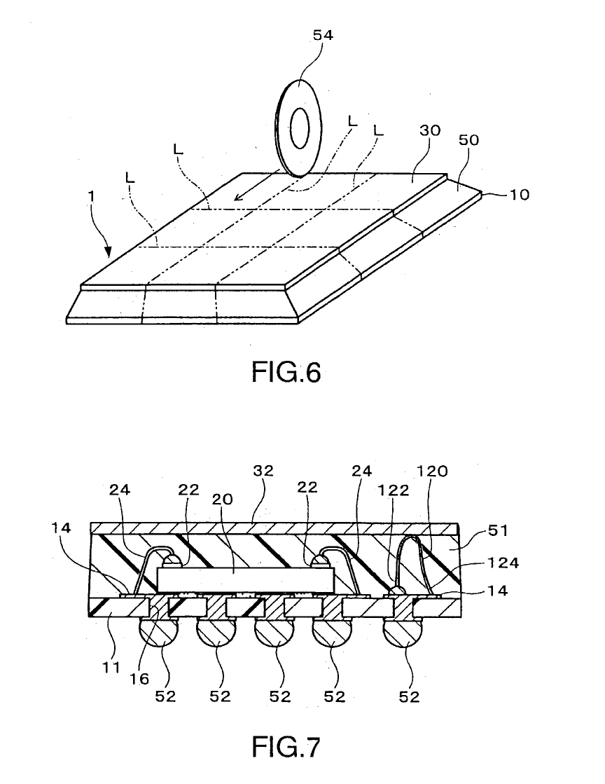

The semiconductor device 1 (incorporating the multiple semiconductor dies 20) is then diced, sliced, as shown in FIG. 6. More specifically, the sealed part 50 and substrate plate 10 are cut completely through the heat sink sheet 30. A cutting tool (such as a blade used for cutting a silicon wafer) 54 can be used. The semiconductor device 1 can be cut from the heat sink sheet 30 side, as shown in FIG. 6, or from the substrate plate 10 side. Pre-forming cutting lines L (indicated by the broken lines) makes it easier to position the semiconductor device 1 for cutting.

It is thus possible using this method to mount multiple heat sinks 32 en masse to a substrate plate 10 by placing a heat sink sheet 30 containing multiple heat sinks 32, or a linked set of multiple heat sinks 32, in the mold 40, a shown in FIG. 4. It is therefore possible to, for example, position multiple heat sinks 32 on multiple semiconductor dies 20 in one step, and thereby improve the productivity of manufacturing semiconductor devices having a heat sink 32.

The present invention shall not be limited to this embodiment and can be varied in many ways. Those parts (including the construction, operation, function, and effect) of the embodiments described below common to the above-described embodiment are omitted in the following descriptions. It should be noted that the present invention also includes configurations that can be achieved by combining parts of multiple embodiments.

Embodiment 2

FIG. 7 shows a semiconductor device according to a second embodiment of the invention. In this embodiment the middle part of wire 120 contacts the heat sink 32. Both end parts (first and second ends 122, 124) of the wire 120 are bonded to wiring pattern 14 on interposer, i.e. substrate, 11.

The material and method of forming the wire 120 can be the same as for wire 26 described above. The wire 120 has first and second ends 122, 124. Second end 124 is the opposite end from first end 122. The first end 122 is bonded to the wiring pattern 14 (such as at a land). In this case a bump could be disposed therebetween. Alternatively, if the material of the wire 120 and bump are the same, the first end 122 could also include the bump. Then, in the example shown in FIG. 7, the second end 124 is also bonded to wiring pattern 14 (such as at a land). A bump (not shown in the figure) could also be disposed therebetween.

As shown in FIG. 7 the height of the loop in wire 120 is higher than the loop in wires 24. More specifically as shown in FIG. 7, the middle part of wire 120 (the part exempting the first and second ends 122, 124) is drawn towards the heat sink 32 so that it is higher than the middle part of wire 24.

In other words, wire 120 extends from the first end 122 towards heat sink 32 to a height at which it contacts heat sink 32. Wire 120 then draws from the middle part contacting the heat sink 32 to the substrate 10 and electrically connected to the wiring pattern 14 at second end 124. That is, the heat sink 32 is electrically connected to the wiring pattern 14 by the middle part of the wire 120 contacting the heat sink 32.

Alternatively, the semiconductor die 20 could be mounted face-down on substrate interposer 11. In this case contact bumps are often formed on the electrodes 22 of the semiconductor die 20.

The effects described in the previous embodiment are also achieved by the present embodiment. It should be noted that a manufacturing method for this semiconductor device can be derived from the above-described particulars and further description is therefore omitted.

Embodiment 3

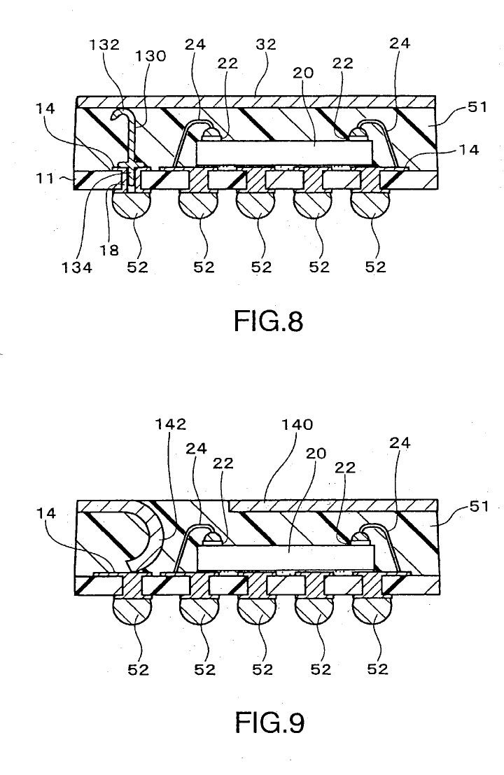

FIG. 8 shows a semiconductor device according to a third embodiment of the invention. In this embodiment a pin 130 on the substrate 11 contacts the heat sink 32. The pin 130 is electrically connected to the wiring pattern 14 of the substrate 11, and extends to the heat sink 32. As in the previous first and second embodiments, pin 130 preferably couples heat sink 32 to a grounding line on wiring pattern 14.

The pin 130 can be any material insofar as it is electrically conductive. For example, the pin 130 could be made of the same material as the wiring pattern 14. The shape of the pin 130 is not specifically limited, but preferably has a specific height. The pin 130 is positioned on substrate 10. The base end part 134 of the pin 130 could, for example, be inserted to a through-hole 18 in substrate 11. This makes it possible to dependably fix the pin 130 to substrate 11. The pin 130 could also be simply electrically connected to the wiring pattern 14 through the through-hole 18. It should be noted that in the example shown in FIG. 8 a conductive material is preferably disposed on the inside wall of the through-hole 18 by a plating method, for example. As a variation, the pin 130 could be simultaneously formed three-dimensionally during the wiring pattern 14 formation process. In this case the pin 130 is an integral part of the wiring pattern 14.

The distal end part 132 of the pin 130 contacts the heat sink 32. As shown in FIG. 8 the distal end part 132 of the pin 130 is curved into a J-shape (more specifically, to an inverted,- or upside-down, J shape). More specifically, the distal end part 132 is flexed. This makes it possible to increase the contact area between the pin 130 and heat sink 32. The pin 130 could also have resilience in the direction of the heat sink 32 (upward (or downward)). The pin 130 could be a spring or it could be a spring connector. An electrically conductive material with resilience could also be used for the pin 130. This can alleviate stress applied to the heat sink by the pin 130.

With this embodiment of the invention a pin disposed to the substrate contacts the heat sink. The wiring pattern and heat sink can be electrically connected more easily by simply providing a pin of a specific height.

The effects described in the previous embodiments are also achieved by the present embodiment. It should be noted that a manufacturing method for this semiconductor device can be derived from the above-described items and further description is therefore omitted.

Embodiment 4

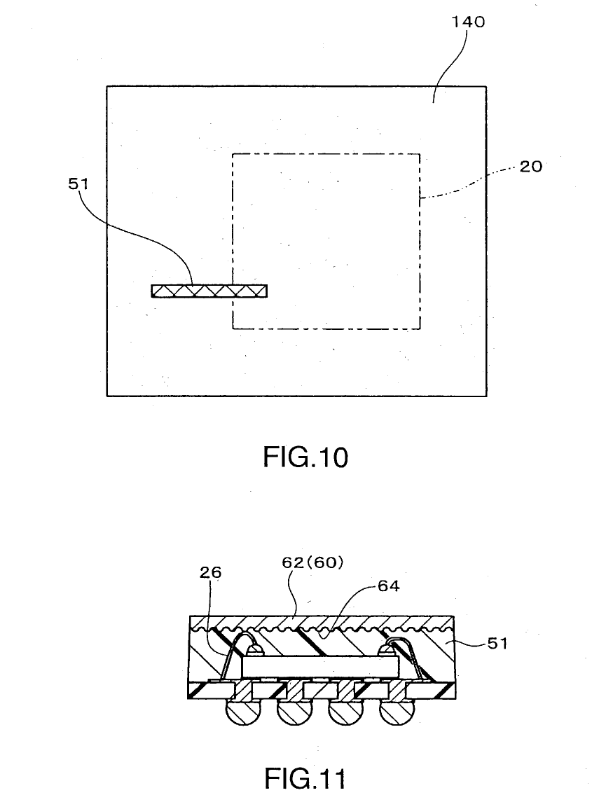

FIG. 9 and FIG. 10 show a semiconductor device according to a fourth embodiment of the invention. More specifically, FIG. 9 is a sectional view of the semiconductor device, and FIG. 10 is a top view of the semiconductor device shown in FIG. 9. In this embodiment, part of the heat sink 140 is electrically connected to the wiring pattern 14, through which heat sink 140 may be coupled to electrical ground. The heat sink 140 is substantially identical to the heat sink 32 described above with the differences described below.

As shown in FIG. 9 part of the heat sink 140 may be bent toward the substrate 10. The curved part 142 can be formed as shown in FIG. 10 at a part (an inside part) of the heat sink 140 other than the edge. In the example shown in FIG. 10 a part of the heat sink 140 is cut into a long shape (a long, slender shape) at some part other than the sides (the two opposing long sides and remaining short sides). The curved part 142 can be bent after being cut with a cutting tool (cutter), and is shaped before the sealing process. It should be noted that as shown in FIG. 10 the sealed part 51, i.e. the sealant, is exposed in the opened area where the curved part 142 of the heat sink 140 is bent down toward wiring pattern 14.

Alternatively, the curved part 142 could be formed at an edge of the heat sink 140. That is, the heat sink 140 could be cut at one of the side edges to form the curved part 142.

This embodiment achieves the effects described above and also helps suppress the cost because the part count of the semiconductor device can be reduced. The manufacturing method of this semiconductor device is as described above.

Embodiment 5

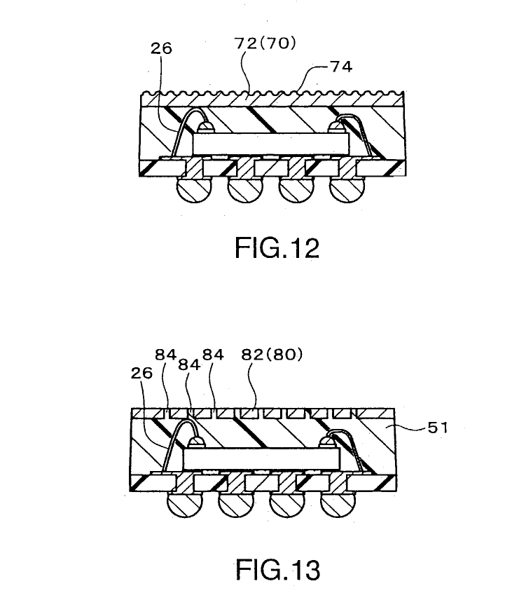

FIG. 11 and FIG. 12 show a semiconductor device according to a fifth embodiment of the invention. In the following fifth to ninth embodiments, the shape of the heat sink and the manufacturing method of the semiconductor device differ from the embodiments described above.

In this fifth embodiment, at least one surface (one or both surfaces) of the heat sink sheet 60 (i.e. heat sink 62) is made a rough surface.

As shown in FIG. 11, the surface 64 of heat sink sheet 60 facing the substrate 10 can be rough. The surface 64 of heat sink set 60 can be roughened so as to remove its smoothness. The surface 64 of heat sink sheet 60 can be roughened mechanically using sandblasting, or physically using plasma, UV radiation, or ozone, for example, or chemically using an etchant. The surface could also be roughened by dimpling. It should be noted that it is sufficient to roughen the part of the heat sink sheet 60 that will be diced to form heat sink 62.

With this configuration, the side of the heat sink sheet 60 (or heat sink 62) facing the substrate 10 is the part that contacts the sealant (or sealed part 51). This increases the adhesion area between the heat sink set 60 and sealant, increases the physical and chemical bond strength, and improves adhesion therebetween.

As shown in FIG. 12, in a modification of the fifth embodiment, the exposed surface 74 of heat sink sheet 70 (heat sink 72) facing away from the substrate 10 can be a roughened surface. In the example shown in FIG. 12 the roughened surface 74 of heat sink sheet 70 is exposed from the sealant. It is sufficient in this case for the heat sink 72 part of the heat sink sheet 70 to have a roughened surface.

The exposed area of the heat sink 72 can be increased by thus making the surface 74 of the heat sink sheet 70 (or heat sink 72) facing away from the substrate 10 rough. Heat radiation from the semiconductor chip can thereby be further improved.

While not shown in the figures it is also possible to make both surfaces of the heat sink set (at least in the parts that become heat sinks) rough. This will improve both adhesion and heat radiation as described above.

Embodiment 6

FIG. 13 shows a semiconductor device according to a sixth embodiment.

In this embodiment a plurality of through-holes 84 are formed in the heat sink sheet 80 (i.e. in the heat sink 82 after dicing in FIG. 13). These through-holes 84 pass through from the surface of the heat sink sheet 80 facing the substrate 10 to its opposite surface. The through-holes 84 are formed at least in the part of heat sink sheet 80 that will form heat sink 82. The multiple through-holes 84 can be formed chemically by etching or physically using a drill, for example.

Adhesion between the heat sink sheet 80 (or heat sink 82) and sealant (or sealed part 51) can be improved by forming these through-holes 84 in the heat sink set 80 because the sealant also enters, and anchors itself at, the through-holes 84.

Embodiment 7

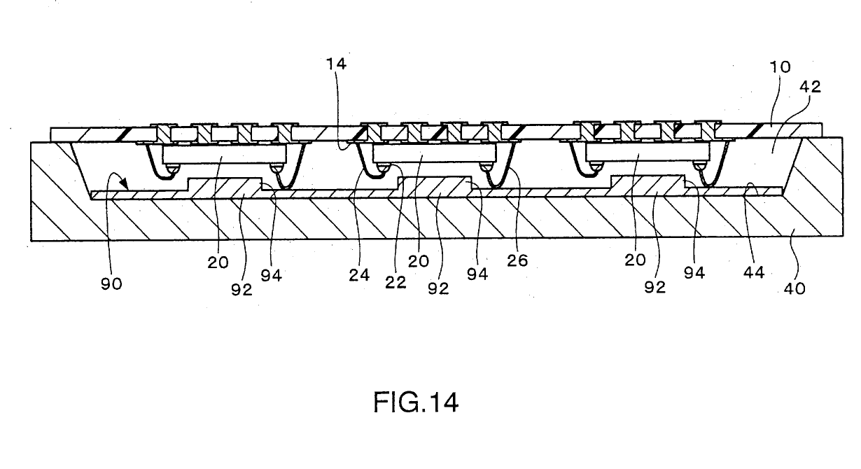

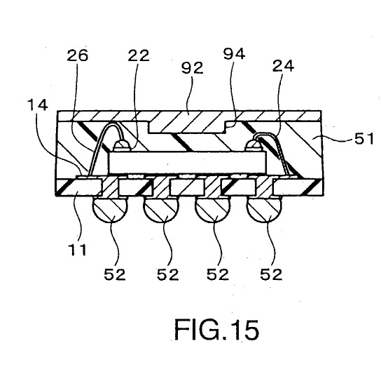

FIG. 14 and FIG. 15 show a manufacturing method for a semiconductor device according to a seventh embodiment of the invention. In this preferred embodiment protruding lands 94 are formed on the heat sink sheet 90.

As shown in FIG. 14 the lands 94 are placed in the cavity 42 of mold 40 facing towards dies 20. That is, the lands 94 are oppose the semiconductor dies 20.

The lands 94 are formed on the parts of the heat sink sheet 90 that become the multiple heat sinks 92. That is, each land 94 is formed so that it is opposite one of the semiconductor dies 20. The planar shape of the land 94 may be smaller than the planar shape of the semiconductor die 20. For example, if multiple electrodes 22 are formed along each side of the semiconductor die 20 as shown in FIG. 14, the lands 94 can have a planar shape that fits inside the area enclosed by the multiple electrodes 22. Contact between the heat sink sheet 90 and wires 24 can thus be avoided because the lands 94 can be located avoiding the wires 24.

Heat radiation from the semiconductor chip 20 can also be improved because the thickness of the heat sink 92 can be partially increased by the lands 94 without being limited by the height of the wire 24 loops. It will also be noted that the lands 94 can be disposed as shown in FIG. 14 so that they do not contact the surface of the semiconductor die 20.

The lands 94 can be formed on the heat sink sheet 90 using a half-etching method, for example, or by plating. In both cases the heat sink sheet 90 is a single member. The lands 94 could also be positioned on the heat sink sheet 90 by fixing a separate member (of the same or different material) to the parts of the heat sink sheet 90 that will become the heat sinks 92. In this case the two parts can be fixed together by welding, bonding, or mechanical joining (such as caulking).

Other specific processes (sealing and cutting) are then performed to produce the individual semiconductor devices as shown in FIG. 15.

In this embodiment of the invention the lands 94 of the heat sinks 92 face the semiconductor chip 20. Heat radiation from the semiconductor chip 20 can be thus be further improved because the distance between the heat sinks 92 and semiconductor chip 20 is shortened.

Embodiment 8

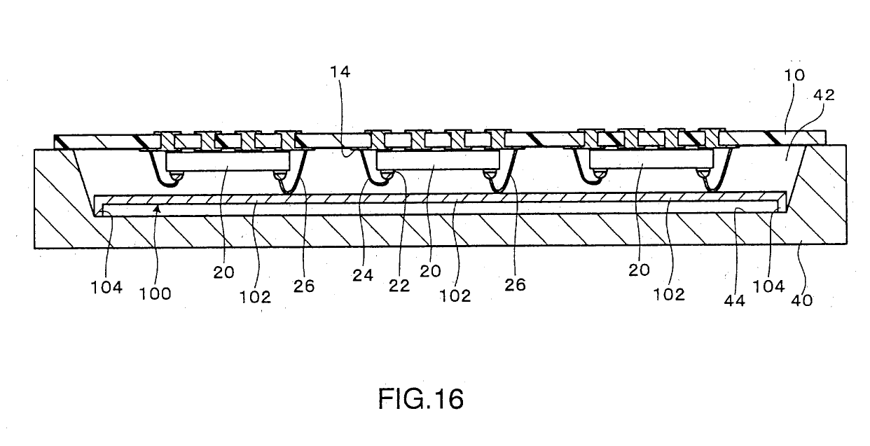

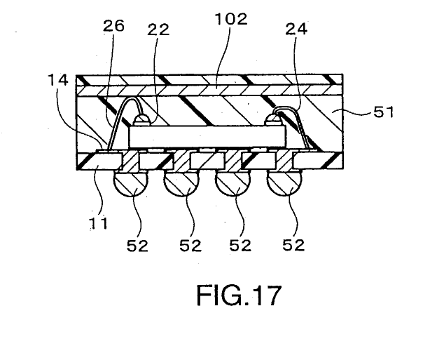

FIG. 16 and FIG. 17 show the manufacturing method of a semiconductor device according to an eighth embodiment of the invention. A lip 104 is formed on the outside edge part of the heat sink sheet 100 in this embodiment. That is, the outside of the heat sink set 100 is raised away from the inner bottom region of mold 40.

As shown in FIG. 16 the heat sink 102 parts of the heat sink sheet 100 are raised above the bottom 44 of the cavity 42 by the lip 104. In the example shown in FIG. 16 the heat sink set 100 does not touch the bottom 44 of the cavity 42 except at the lip 104.

The lip 104 can be formed around the entire perimeter of the heat sink set 100 or only in parts (such as the corners or only two sides of a rectangular heat sink sheet 100). The lip 104 can be formed from a single part by a half-etching method, plating, or mechanical drawing, for example. The lip 104 could also be provided by fixing a separate member (of either the same or different material) to the outside edge of the heat sink set 100.

Other specific processes (sealing and cutting) are then performed to obtain the individual semiconductor devices, as shown in FIG. 17. Because the heat sink 102 is sealed while lifted off the inner bottom 44 of mold 40, the surface of the heat sink 102 facing away from the substrate 10 can also be covered with sealant as shown in FIG. 17. The heat radiation of the semiconductor die 20 can thus be improved even without externally exposing the heat sink 102. It should be noted that, as shown in FIG. 17, the heat sink 102 may be exposed from a side part of the semiconductor device.

Embodiment 9

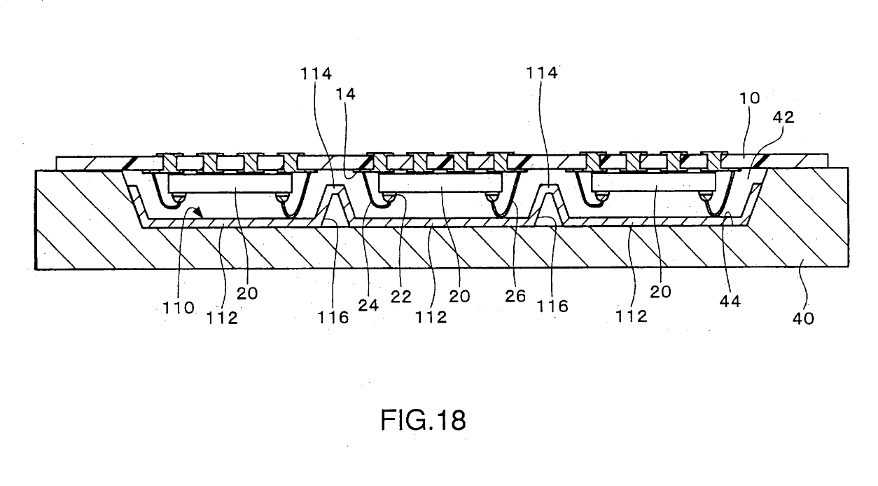

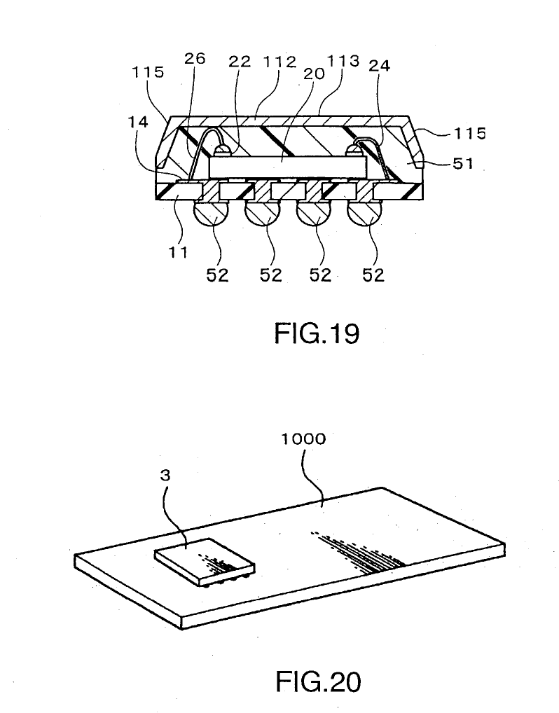

FIG. 18 and FIG. 19 show a manufacturing method for a semiconductor device according to a ninth embodiment of the present invention. This embodiment has ribs 114 with a substantially continuous shape in a longitudinal section formed on the heat sink sheet 110 along the cutting lines L (as previously shown in FIG. 6 in accordance with a previous emgbodiment). More specifically, in a plan view of the heat sink sheet 110, the ribs 114 form strips (with a specific width) along the cutting lines L, and the areas defined by the by the ribs 114 become the heat sinks 112. The width of the ribs 114 is preferably greater than the width of the blade of the cutting tool 54 (see FIG. 6) used in the cutting (i.e. dicing) process. This makes it possible to easily cut along the center axis of the ribs 114.

As shown in FIG. 18 the ribs 114 are set facing the open side of the cavity 42 in the mold 40. That is, the ribs 114 are set facing the substrate 10. In the example shown in FIG. 18 the ribs 114 are tapered so that the peak part of the rib is narrow.

As shown in FIG. 18 valleys 116 can be formed in the heat sink sheet 110 on the side opposite the ribs 114. These valleys 116 also have a substantially continuous shape in longitudinal section. In other words, the valleys 116 form trenches along the cutting lines L when seen in a plan view of the heat sink sheet 110. In the example shown in FIG. 14 the valleys 116 are tapered in from a wide mouth. If the heat sink sheet 110 is then sliced from the valley 116 side thereof, the blade of the cutting tool 54 can be easily aligned with the center axis of the valley 116 (or rib 114), and the heat sink set 110 can be accurately cut. It should be noted that the valleys 116 do not need to be filled with sealant.

The ribs 114 (and valleys 116) can be formed on the heat sink sheet 110 from a single piece by mechanical drawing. They could alternatively be formed by affixing separate parts.

Other specific processes (sealing and cutting) are then performed to obtain the individual semiconductor devices as shown in FIG. 19. Because the ribs 114 (or valleys 116) are cut in the cutting process, the heat sink 112 is exposed at the top 113 and side 115 parts of the individual semiconductor device. In the example shown in FIG. 19 the heat sink 112 forms part of a frustum of a pyramid. The heat sinks 112 could alternatively form part of a sphere (such as a hemisphere).

The heat sink 112 thus surrounds the semiconductor die 20. As a result, the heat radiation of the semiconductor die 20 can be further improved. Furthermore, the electrical characteristics of the semiconductor die 20 can be made more stable by electrically connecting the ground potential part of the wiring pattern 14 to the heat sink 112. Furthermore, the location of the cutting lines L can be easily recognized as a result of forming the valleys 116, and positioning for cutting is easier.

Embodiment 10

FIG. 20 shows a circuit board for applying the embodiments described above. A semiconductor device 3 is mounted on the circuit board 1000. The circuit board 1000 is commonly an organic substrate made of glass epoxy, for example. A wiring pattern of copper, for example, is formed to produce the desired circuits on the circuit board 1000, and the external electrodes of this semiconductor device 3 are bonded to this wiring pattern.

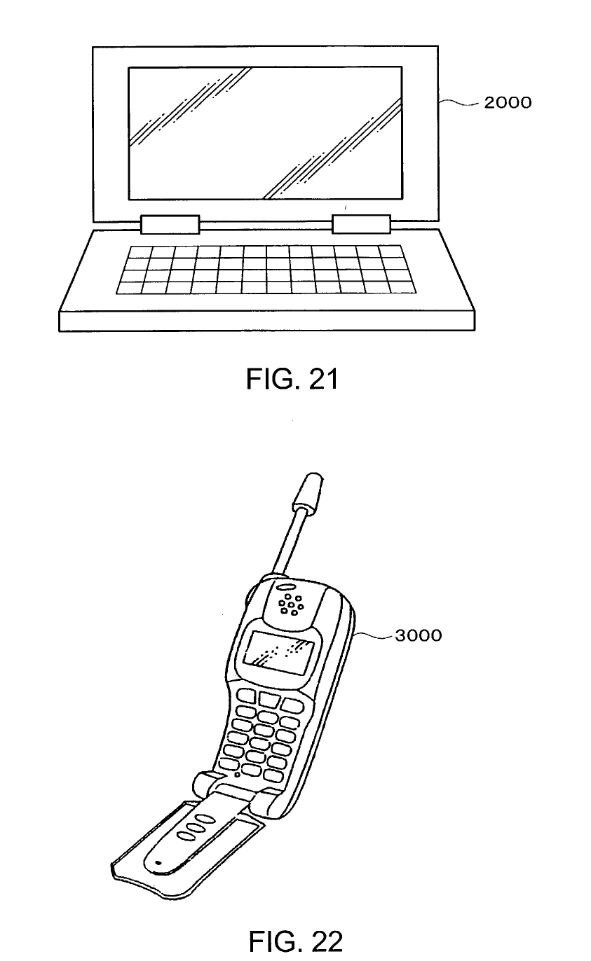

One example of an electronic device having a semiconductor chip according to the present invention is a notebook type personal computer 2000 as shown in FIG. 21, and another is a cellular telephone 3000 as shown in FIG. 22.

The present invention shall not be limited to the embodiments described above and can be varied in many ways. The invention includes, for example, configurations practically identical (for example, configurations of the same function, method, and result, or configurations of the same object and result) to the configurations described in the above embodiments. The invention also includes configurations replacing parts not fundamental to the configurations of the embodiments described above. Yet further, the invention includes configurations having the same operational effect and configurations capable of achieving the same object as the configurations described in the above embodiments. Yet further, the invention includes configurations adding known technology to the configurations described in the above embodiments.

While the invention has been described in conjunction with several specific embodiments, it is evident to those skilled in the art that many further alternatives, modifications and variations will be apparent in light of the foregoing description. Thus, the invention described herein is intended to embrace all such alternatives, modifications, applications and variations as may fall within the spirit and scope of the appended claims.

What is claimed is:

1. A semiconductor device comprising:
a substrate on which a wiring pattern is formed;
a semiconductor die mounted on the substrate;
a sealing part for sealing the semiconductor die on the substrate; and
a heat radiation body supported above the substrate by the sealing part;
wherein the heat radiation body is electrically connected to part of the wiring pattern.

2. A semiconductor device as described in claim 1, further comprising:
a wire pulled toward the heat radiation body with a first end part thereof bonded to the wiring pattern;
wherein the heat radiation body is electrically connected to the wiring pattern by a middle part of the wire that contacts the heat radiation body.

3. A semiconductor device as described in claim 2, wherein the semiconductor die is positioned with a surface having electrodes facing away from the substrate; and
wherein a second end part of the wire is bonded to at least one of said electrodes of the semiconductor die.

4. A semiconductor device as described in claim 2, wherein a second end part of the wire is electrically connected to the wiring pattern of the substrate.

5. A semiconductor device as described in claim 1, further comprising a pin positioned on the substrate, said pin having a base end part coupled to said wiring pattern and having a distal end part extending toward the heat radiation body;
wherein the heat radiation body is electrically connected to the wiring pattern due to the distal end part of the pin contacting the heat radiation body.

6. A semiconductor device as described in claim 5, wherein the substrate has a through-hole electrically connected to the wiring pattern, and
the base end part of the pin is inserted in the through-hole.

7. A semiconductor device as described in claim 5, wherein the pin is flexible at least at said distal end part that contacts the heat radiation body.

8. A semiconductor device as described in claim 1, wherein part of the heat radiation body is curved toward the substrate, and
the curved part of the heat radiation body contacts the wiring pattern.

9. A semiconductor device as described in claim 1, wherein the surface side of the heat radiation body opposite the substrate is not covered by the sealing part.

10. A semiconductor device as described in claim 1, wherein the surface side of the heat radiation body opposite the substrate is covered by the same material as said sealing part.

11. A semiconductor device as described in claim 10, wherein the heat radiation body is exposed at a side edge of the sealing part.

12. A semiconductor device as described in claim 1, wherein at least one surface of the heat radiation body is rough.

13. A semiconductor device as described in claim 1, wherein a plurality of through-holes are formed in the heat radiation body; and
the inside of the through-holes is filled with the same material as the sealing part.

14. A semiconductor device as described in claim 1, wherein the heat radiation body has a mesa-shaped part protruding toward the substrate.

15. A circuit board having mounted thereon a semiconductor device as described in claim 1.

16. An electronic device having a semiconductor device as described in claim 1.

17. A manufacturing method for a semiconductor device comprising:
(a) setting a heat radiation body in a mold's cavity;
(b) setting a substrate having a wiring pattern and multiple semiconductor dies mounted thereon on the mold so that the semiconductor dies are located inside the cavity; and
(c) concurrently sealing the multiple semiconductor dies and affixing the heat radiation body to the substrate by filling the cavity with a sealant;
wherein in a part of the wiring pattern is placed in electrical connect with the heat radiation body prior to step (c) and the sealing process of step (c) preserves the electrical contact.

18. A semiconductor device manufacturing method as described in claim 17, further comprising:
bonding a first end part of a wire to the wiring pattern before step (b); and
in step (c) adding the sealant with a contact part of the wire distant from said first end part contacting the heat radiation body.

19. A semiconductor device manufacturing method as described in claim 18, wherein the semiconductor die is positioned with a surface having electrodes facing away from the substrate, and said contact part is a mid-section of said wire, said semiconductor device manufacturing method further comprising:
bonding a second end part of the wire to an electrode of the semiconductor die before step (b).

20. A semiconductor device manufacturing method as described in claim 18, wherein said contact part is a mid-section of said wire, and a second end part of the wire is bonded to the wiring pattern of the substrate before step (b).

21. A semiconductor device manufacturing method as described in claim 17, further comprising:
positioning a pin on the substrate before step (b), and
in step (c) adding the sealant with a distal end of the pin contacting the heat radiation body.

22. A semiconductor device manufacturing method as described in claim 21, wherein the substrate has a through-hole electrically connected to the wiring pattern, and said semiconductor device manufacturing method further includes:
inserting a base end part of the pin, distant from said distal end, into the through-hole.

23. A semiconductor device manufacturing method as described in claim 21, wherein the pin is made to be flexible in the vicinity of the heat radiation body.

24. A semiconductor device manufacturing method as described in claim 17, further comprising:
bending a part of the heat radiation body so it is raised before step (a), and
in step (c) adding the sealant with the bent part of the heat radiation body contacting the wiring pattern.

25. A semiconductor device manufacturing method as described in claim 17, wherein:
the multiple semiconductor dies are mounted in a planar arrangement on the substrate;
step (a) includes placing an integral set of multiple heat radiation bodies in a mold cavity;
in step (b) setting the substrate so that the multiple semiconductor dies are located inside the cavity opposite a respective heat radiation body; and
in step (c) sealing the multiple semiconductor dies and affixing the set of multiple heat radiation bodies.

26. A semiconductor device manufacturing method as described in claim 25, further comprising after step (c):
(d) producing individually packaged chips each having a respective heat radiation body by cutting the sealing part and substrate together with the heat radiation body set.
